(19) United States
(12) Patent Application Publication
(10) Pub. No.: US 2025/0329358 A1
(43) Pub. Date: Oct. 23, 2025

(54) WRITE TRAINING CIRCUIT, SEMICONDUCTOR DEVICE, AND DATA PROCESSING SYSTEM INCLUDING WRITE TRAINING CIRCUIT

(71) Applicant: SK hynix Inc., Icheon-si Gyeonggi-do (KR)

(72) Inventors: Jae Hyeong HONG, Icheon-si Gyeonggi-do (KR); Beom Kyu SEO, Icheon-si Gyeonggi-do (KR); Keun Seon AHN, Icheon-si Gyeonggi-do (KR); Sung Hwa OK, Icheon-si Gyeonggi-do (KR); Jung Hwan LEE, Icheon-si Gyeonggi-do (KR); Ji Young LEE, Icheon-si Gyeonggi-do (KR); Jun Seo JANG, Icheon-si Gyeonggi-do (KR); Jae Hoon JUNG, Icheon-si Gyeonggi-do (KR); Eun Ji CHOI, Icheon-si Gyeonggi-do (KR)

(73) Assignee: SK hynix Inc., Icheon-si Gyeonggi-do (KR)

(21) Appl. No.: 18/823,324

(22) Filed: Sep. 3, 2024

(30) Foreign Application Priority Data
Apr. 19, 2024 (KR) 10-2024-0052709

(51) Int. Cl. G11C 7/10; G06F 3/06; G11C 7/22

(52) U.S. Cl. CPC G11C 7/1096; G11C 7/222

(57) ABSTRACT

A write training circuit includes a data receiving circuit, a strobe signal processing circuit, and a skew detection circuit. The data receiving circuit receives data input according to a plurality of multi-phase clock signals to generates received data. The strobe signal processing circuit generates the plurality of multi-phase clock signals by dividing a data strobe signal into divided signals and delaying the divided signals by a predetermined time period. The skew detection circuit generates a replication clock signal corresponding to one of the plurality of multi-phase clock signals and generates skew information according to the replication clock signal. The skew detection circuit generates the skew information under external control or independently of external control depending on which of a plurality of external commands is received.

### CROSS-REFERENCES TO RELATED APPLICATION

The present application claims priority under 35 U.S.C. § 119 (a) to Korean patent application number 10-2024-0052709 filed on Apr. 19, 2024, in the Korean Intellectual Property Office, which application is incorporated herein by reference in its entirety.

### BACKGROUND

### 1. Technical Field

Various embodiments generally relate to a semiconductor device, including but not limited to a write training circuit and a semiconductor memory apparatus and a data processing system including the write training circuit.

### 2. Related Art

Conventional semiconductor memory apparatus perform a write leveling operation separately from, or not simultaneously with, a write training operation.

The write leveling operation compensates for the time difference between a clock signal used inside the semiconductor memory apparatus and a data strobe signal provided externally.

The write training operation is a process including internally multi-phasing a data strobe signal supplied from outside the semiconductor memory apparatus to detect and compensate for variations in the timing of externally latched data.

FIG. 1 is a diagram illustrating a prior art write training operation.

Referring to FIG. 1, in the prior art, the write training operation WTRN cannot be performed in parallel with a normal operation, such as a data input operation in response to a write command or a data output operation in response to a read command, and the write training operation WTRN is performed in a separate time period between the data input operation and the data output operation. The write training operation WTRN is performed as often as the user desires.

As described above, in the prior art, the write training operation WTRN is performed in a separate interval between the data input operation and the data output operation, which increases the time required for data input and data output of the semiconductor memory apparatus.

### SUMMARY

In an embodiment, a write training circuit may include a data receiving circuit, a strobe signal processing circuit, and a skew detection circuit. The data receiving circuit may be configured to receive data input according to a plurality of multi-phase clock signals to generate received data. The strobe signal processing circuit may be configured to generate the plurality of multi-phase clock signals by dividing a data strobe signal into divided signals and delaying the divided signals by a predetermined time period. The skew detection circuit may be configured to generate a replication clock signal corresponding to one of the plurality of multi-phase clock signals and may be configured to generate skew information according to the replication clock signal. The skew detection circuit may be configured to generate the skew information under external control or independently of external control depending on which of a plurality of external commands is received.

In an embodiment, a semiconductor device may include a semiconductor memory apparatus configured to perform a normal operation when a command for the normal operation is received and may be configured to perform a write training operation during a time period during which the normal operation is performed. The write training operation may comprise internally multi-phase processing a data strobe signal provided from an external device to determine a time to latch data provided from the external device.

In an embodiment, a data processing system may include a semiconductor memory apparatus and a controller. The semiconductor memory apparatus may be configured to perform a write training operation including determining a time to latch data according to a plurality of multi-phase clock signals that are internally generated based on a data strobe signal during a time period during which a normal operation is performed and outputting the time as skew information, may be configured to perform the write training operation under external control when a write training enable command is received, and may be configured to perform the write training operation independently of external control when a write training internal processing enable command is received. The controller may be configured to provide a plurality of commands including the write training enable command and the write training internal processing enable command, the data, and the data strobe signal to the semiconductor memory apparatus, and may be configured to adjust timing of the data strobe signal according to the skew information.

In an embodiment, a method may include performing, by a semiconductor memory apparatus, a normal operation during a first time period in response to receiving a command; and performing, by the semiconductor memory apparatus during a second time period within the first time period, a write training operation including multi-phase processing a received data strobe signal to determine a time at which data provided from an external device is latched.

### BRIEF DESCRIPTION OF THE DRAWINGS

FIG. 1 is a diagram illustrating a prior art write training operation.

FIG. 2 is a diagram illustrating a multi-operation function including write training according to an embodiment of the present disclosure.

FIG. 3 is a diagram illustrating a multi-operation function including write training according to an embodiment of the present disclosure.

FIG. 4 is a diagram illustrating a multi-operation function including write training according to an embodiment of the present disclosure.

FIG. 5 is a diagram illustrating a configuration of a semiconductor memory apparatus according to an embodiment of the present disclosure.

FIG. 6 is a diagram illustrating a configuration of a data processing system according to an embodiment of the present disclosure.

FIG. 7 is a diagram illustrating a multi-operation function including write training according to an embodiment of the present disclosure.

FIG. 8 is a diagram illustrating a multi-operation function including write training according to an embodiment of the present disclosure.

FIG. 9 is a diagram illustrating a configuration of a write training circuit according to an embodiment of the present disclosure.

FIG. 10 is a diagram illustrating a configuration of a data receiving circuit according to an embodiment of the present disclosure.

FIG. 11 is a diagram illustrating a configuration of a strobe signal processing circuit according to an embodiment of the present disclosure.

FIG. 12 is a diagram illustrating a configuration of a strobe signal replication circuit according to an embodiment of the present disclosure.

FIG. 13 is a diagram illustrating a configuration of a timing control circuit according to an embodiment of the present disclosure.

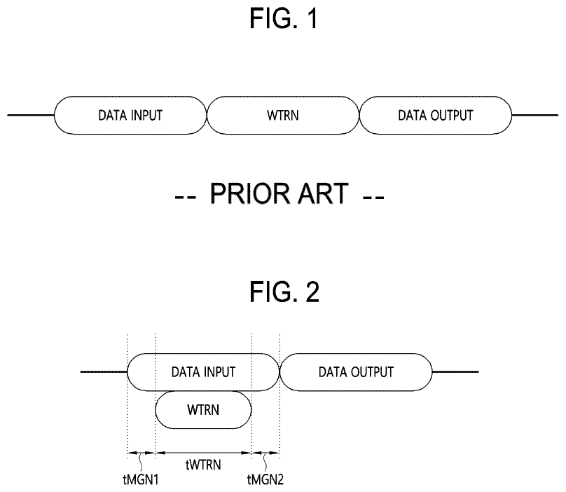

### DETAILED DESCRIPTION

Various embodiments of the present disclosure may reduce the time required for data input and data output of a semiconductor memory apparatus. Various embodiments of the present disclosure may reduce the control-related load on an external device controlling the semiconductor memory apparatus by self-processing a write training operation with a minimal or a reduced quantity of external commands.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

FIG. 2 is a diagram illustrating a multi-operation function including write training according to an embodiment of the present disclosure. FIG. 2 illustrates an example of a multi-operation function including write training when a normal operation is performed sequentially, for example, a data input operation in response to a write command and a data output operation in response to a read command.

Referring to FIG. 2, the present disclosure performs a write training operation WTRN in parallel with a data input operation, for example, the write training operation WTRN is performed for a predetermined time period tWTRN within a time period during which the data input operation is performed.

The write training operation WTRN starts after a first timing margin tMGN1 from the start of the data input operation and ends before a second timing margin tMGN2 from the end of the data input operation. The first timing margin tMGN1 and the second timing margin tMGN2 with respect to the progress of the write training operation WTRN show an example of stable progress of the data input operation. Optionally, one or both of the first timing margin tMGN1 and the second timing margin tMGN2 may be utilized to start or end the write training operation WTRN.

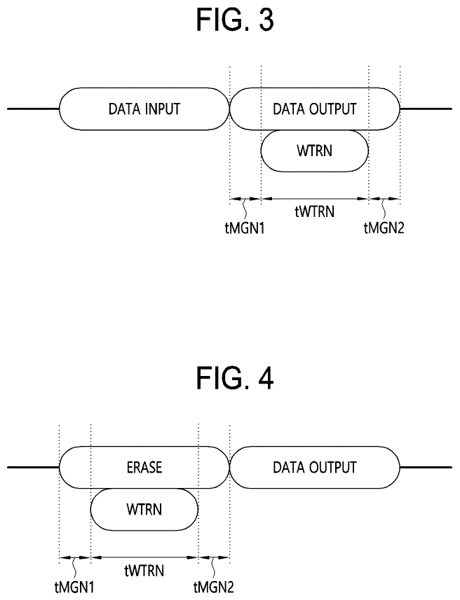

FIG. 3 is a diagram illustrating a multi-operation function including write training according to an embodiment of the present disclosure. FIG. 3 illustrates another example of a multi-operation function including write training where a data input operation and a data output operation are performed sequentially.

Referring to FIG. 3, a write training operation WTRN is performed in parallel with a data output operation, for example, the write training operation WTRN is performed for a predetermined time period tWTRN within a time period during which the data output operation is performed.

The write training operation WTRN starts after a first timing margin tMGN1 from the start of the data output operation and ends before a second timing margin tMGN2 from the end of the data output operation. The first timing margin tMGN1 and the second timing margin tMGN2 with respect to the progress of the write training operation WTRN show an example of stable progress of the data output operation. Optionally, one or both of the first timing margin tMGN1 and the second timing margin tMGN2 may be utilized to start or end the write training operation WTRN.

FIG. 4 is a diagram illustrating a multi-operation function including write training according to an embodiment of the present disclosure. FIG. 4 illustrates an example of a multi-operation function including write training when an erase operation and a data output operation are performed sequentially.

Referring to FIG. 4, a write training operation WTRN is performed in parallel with an erase operation, for example, the write training operation WTRN is performed for a predetermined time period tWTRN within a time period during which the erase operation is performed.

The write training operation WTRN starts after a first timing margin tMGN1 from the start of the erase operation and ends before a second timing margin tMGN2 from the end of the erase operation. The first timing margin tMGN1 and the second timing margin tMGN2 with respect to the progress of the write training operation WTRN show an example of stable progress of the erase operation. Optionally, one or both of the first timing margin tMGN1 and the second timing margin tMGN2 may be utilized to start or end the write training operation WTRN.

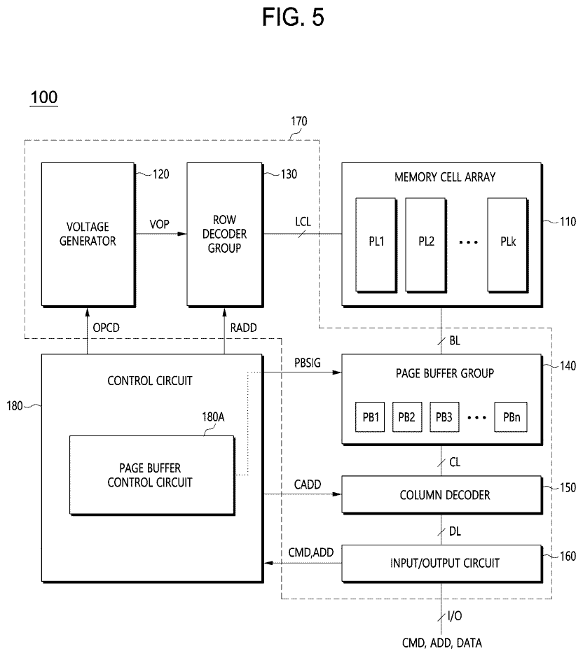

FIG. 5 is a diagram illustrating a configuration of a semiconductor memory apparatus 100 according to an embodiment of the present disclosure.

The semiconductor memory apparatus 100 is configured to perform a multi-operation function. The multi-operation function includes at least one of: performing a data input operation according to a write command in parallel with a write training operation; performing a data output operation according to a read command in parallel with a write training operation; and performing an erase operation in parallel with a write training operation.

The write training operation is performed, for example, by internally multi-phase processing a data strobe signal provided from outside the semiconductor memory apparatus 100 to detect or determine a time at which the data provided from outside the semiconductor memory apparatus 100 is latched. The write training operation is performed by notifying the semiconductor memory apparatus 100 of the detected or determined time and adjusting accordingly timing of the data strobe signal by an amount corresponding to a variation in the detected or determined time outside the semiconductor memory apparatus 100.

Referring to FIG. 5, the semiconductor memory apparatus 100 includes a memory cell array 110, a peripheral circuit 170, and a control circuit 180.

The memory cell array 110 includes a plurality of memory cells arranged in at least one memory plane. For example, the memory cell array 110 includes a first memory plane PL1 to a kth memory plane PLk, where k is a positive integer. Each of the memory planes PL1 through PLk includes memory blocks. The memory blocks may be formed in a two-dimensional structure or a three-dimensional structure. Memory blocks having a two-dimensional structure include memory cells arranged parallel to a substrate. Memory blocks having a three-dimensional structure include memory cells stacked perpendicular to the substrate. The memory cells store one bit, two bits, or more than two bits of data depending on a programming method.

The peripheral circuit 170 is configured to perform a program operation that stores data in the memory cell array 110, a read operation that outputs data stored in the memory cell array 110, and an erase operation that erases data stored in the memory cell array 110. For example, the peripheral circuit 170 includes a voltage generator 120, a row decoder group 130, a page buffer group 140, a column decoder 150, and an input/output circuit 160.

The voltage generator 120 generates, in response to an operation code OPCD, various operating voltages Vop that are used during the program operation, the read operation, and the erase operation. For example, the voltage generator 120 may be configured to generate a program voltage, a pass voltage, a turn-on voltage, a turn-off voltage, a ground voltage, a verification voltage, a read voltage, an erase voltage, and the like in response to the operation code OPCD. The program voltage is a voltage applied to a selected word line during the program operation, which may be used to raise threshold voltages of memory cells. The pass voltage is a voltage applied to unselected word lines during the program or read operation, which may be used to turn on unselected memory cells. The turn-on voltage is a voltage applied to a drain selection line or a source selection line, which may be used to turn on a drain selection transistor or a source selection transistor. The turn-off voltage is a voltage applied to the drain selection line or the source selection line, which may be used to turn off the drain selection transistor or the source selection transistor. The ground voltage may be at 0V. The verification voltage is a voltage applied to a selected word line or all word lines coupled to a selected memory block to determine threshold voltages of the selected memory cells during the program or erase operation. The read voltage is a voltage applied to a selected word line during the read operation, which may be used to determine the data stored in the memory cells. The erase voltage is a voltage applied to a source line during an erase operation, which may be used to lower threshold voltages of the memory cells.

The row decoder group 130 is configured to send the operating voltages Vop to local lines LCL coupled to a selected memory block according to a row address RADD. For example, the row decoder group 130 is coupled to the voltage generator 120 through global lines and to the first to kth memory planes PL1 through PLk through local lines LCL. The row decoder group 130 includes a plurality of row decoders (not shown), each coupled to one of the memory planes PL1 through PLk. Each of the plurality of row decoders is coupled to memory blocks included in the memory planes PL1 through PLk through local lines LCL. The local lines LCL include drain selection lines, word lines, source selection lines, source lines, and so forth.

The page buffer group 140 includes a plurality of page buffers PB1 through PBn, where n is a positive integer. Each of the plurality of page buffers PB1 through PBn may have the same circuit configuration. The plurality of page buffers PB1 through PBn is coupled to the memory cell array 110 through a plurality of bit lines BL. In response to a plurality of page buffer control signals PBSIG, the plurality of page buffers PB1 through PBn adjusts a level of voltage applied to the plurality of bit lines BL and a duration for which voltage is applied to the bit lines BL. The plurality of page buffers PB1 through PBn stores externally supplied data in response to the plurality of page buffer control signals PBSIG. Among the plurality of page buffers PB1 through PBn, page buffers corresponding to remaining sub-verification operations other than verified sub-verification operations, simultaneously precharge the bit lines coupled to the corresponding page buffers. Each of the plurality of page buffers PB1 through PBn determines corresponding sub-verification operations according to stored data. The plurality of page buffers PB1 through PBn may precharge corresponding bit lines by applying a precharge voltage to corresponding bit lines for each of sub-verification operations in response to the plurality of page buffer control signals PBSIG.

The column decoder 150 is configured to transfer data between the page buffer group 140 and the input/output circuit 160 in response to a column address CADD. For example, the column decoder 150 is coupled to the page buffer group 140 through column lines CL and to the input/output circuit 160 through data lines DL.

The input/output circuit 160 passes commands CMD and addresses ADD received from an external device, for example, a controller, to the control circuit 180. The input/output circuit 160 receives data transmitted from the external device in response to a data strobe signal transmitted from the external device and transmits the data to the page buffer group 140 through the column decoder 150. The input/output circuit 160 outputs data transmitted from the column decoder 150 to the external device. The input/output circuit 160 includes a write training circuit that performs a write training operation.

The control circuit 180 outputs the operation code OPCD, the row address RADD, the page buffer control signals PBSIG, and the column address CADD in response to the command CMD and the address ADD. The control circuit 180 controls the peripheral circuit 170 to perform an erase operation on the memory block selected by the address ADD when an input command CMD identifies the erase operation. The control circuit 180 controls the peripheral circuit 170 to perform a read operation on the memory block selected by the address and output read data when the input command CMD identifies the read operation. The control circuit 180 controls the peripheral circuit 170 to perform program and verification operations on the selected memory block when the input command CMD identifies a program operation.

The control circuit 180 includes a page buffer control circuit 180A. In response to the command CMD, the page buffer control circuit 180A generates the page buffer control signals PBSIG that adjust a level of voltage applied to the bit lines BL and a duration for which a voltage is applied to the bit lines BL. The page buffer control signals PBSIGs include various signals that adjust voltages applied to the bit lines BL as well as circuits contained in the plurality of page buffers PB1 through PBn.

The page buffer control circuit 180A adjusts the page buffer control signals PBSIG such that an erase voltage is applied to the bit lines BL during an erase operation. The page buffer control circuit 180A adjusts the page buffer control signals PBSIG such that a precharge voltage is applied to the bit lines BL.

The page buffer control circuit 180A adjusts values of the page buffer control signals PBSIG such that during a program operation, a program-allow voltage is applied to selected bit lines of the bit lines BL and a program-disallow voltage is applied to unselected bit lines.

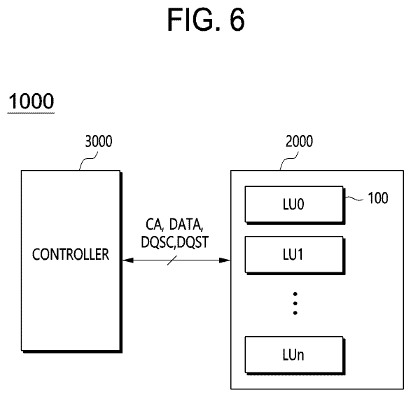

FIG. 6 is a diagram illustrating a configuration of a data processing system 1000 according to an embodiment of the present disclosure.

Referring to FIG. 6, the data processing system 1000 includes a semiconductor device 2000 and a controller 3000.

In the example of FIG. 6, the semiconductor device 2000 includes a plurality of logic units LU0 through Lun, where n is a positive integer. Each of the plurality of logic units LU0 through LUn includes at least one memory die and is also referred to as a semiconductor memory apparatus 100. One or more of the plurality of logic units LU0 through Lun 100 are implemented similarly to the semiconductor memory apparatus 100 described with reference to FIG. 5.

The semiconductor device 2000 is configured to perform a multi-operation function. The multi-operation function includes at least one of: in response to a write command, performing a data input operation in parallel with a write training operation, in response to a read command, performing a data output operation in parallel with a write training operation, and performing an erase operation in parallel with a write training operation. The semiconductor device 2000 provides, to the controller 3000, skew information detected while performing a write training operation WTRN.

The controller 3000 generates and provides a plurality of control signals and commands to the semiconductor device 2000. The controller 3000 transmits/receives data, commands, addresses, and status information to/from the semiconductor device 2000 according to a data input mode, a data output mode, a command input mode, an address input mode, a parameter setting mode, and a status information output mode. During the data input mode, the controller 3000 provides data and data strobe signals DQST, DQSC to the semiconductor device 2000. The controller 3000 adjusts timing of the data strobe signals DQST, DQSC according to skew information provided by the semiconductor device 2000 to the controller 3000.

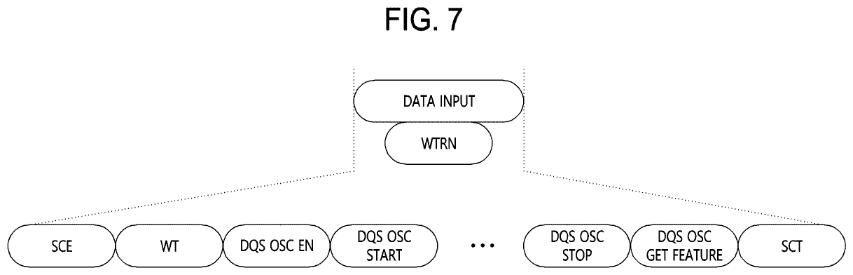

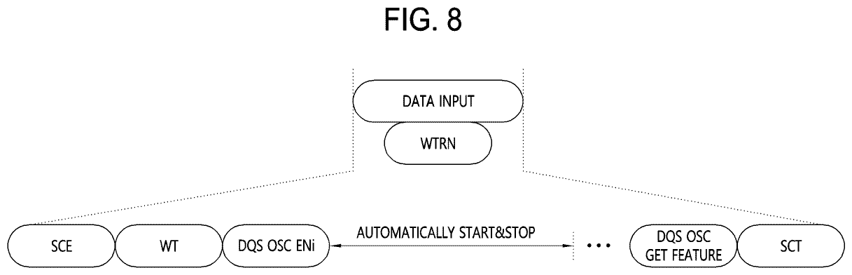

With reference to FIG. 7 and FIG. 8, a detailed operation according to the multi-operation function including write training is described.

FIG. 7 is a diagram illustrating a detailed operation according to the multi-operation function including write training of the present disclosure. FIG. 7 illustrates an example of performing the multi-operation function including write training in accordance with external control, such as external commands provided by the controller 3000.

Referring to FIG. 7, when the controller 3000 provides a select chip enable command SCE to the semiconductor device 2000, the semiconductor device 2000 activates a logic unit 100 from the plurality of logic units LU0 through LUn, for example, LU0, which logic unit 100 is identified by the select chip enable command SCE.

When the controller 3000 provides a write command WT to the semiconductor device 2000, the semiconductor device 2000 performs a data input operation, for example, a program operation on the logic unit LU0 in response to receiving the select chip termination command SCT.

When the controller 3000 provides a write training enable command DQS OSC EN to the semiconductor device 2000, the semiconductor device 2000 performs a preparation operation for a write training operation for the logic unit LU0 in response to receiving the write training enable command DQS OSC EN.

When the controller 3000 provides a write training start command DQS OSC START to the semiconductor device 2000, the semiconductor device 2000 starts to perform a skew information generation operation for the logic unit LU0 in response to receiving the start command DQS OSC START.

When the controller 3000 provides a write training stop command DQS OSC STOP to the semiconductor device 2000, the semiconductor device 2000 stops performing the skew information generation operation for the logic unit LU0 in response to receiving the write training stop command DQS OSC STOP. While performing the skew information generation operation, the semiconductor device 2000 generates and stores skew information. The skew information includes a value corresponding to a time to latch data provided by the controller 3000 using multi-phase clock signals generated by internally multi-phase processing a data strobe signal provided by the controller 3000.

The controller 3000 provides the skew information acquisition command DQS OSC GET FEATURE to the semiconductor device 2000, and in response the semiconductor device 2000 provides the skew information to the controller 3000.

When the controller 3000 provides a select chip termination command SCT to the semiconductor device 2000, the semiconductor device 2000 terminates the multi-operation function including the write training by disabling the logic unit LU0 in response to receiving the select chip termination command SCT.

FIG. 8 is a diagram illustrating an embodiment of a detailed operation according to a multi-operation function including write training of the present disclosure. FIG. 8 illustrates an example in which one or more of the operations of the multi-operation function including write training are performed by the semiconductor device 2000 independently of external control.

Referring to FIG. 8, when the controller 3000 provides a select chip enable command SCE to the semiconductor device 2000, the semiconductor device 2000 activates a logic unit 100 from the plurality of logic units LU0 through LUn, for example, LU0, which logic unit 100 is identified by the select chip enable command SCE.

When the controller 3000 provides a write command WT to the semiconductor device 2000, the semiconductor device 2000 performs a data input operation, for example, a program operation on the logic unit LU0 in response to receiving the write command WT.

When the controller 3000 provides a write training internal processing enable command DQS OSC ENi to the semiconductor device 2000, the semiconductor device 2000 performs a preparation operation for a write training operation for the logic unit LU0 in response to receiving the internal processing enable command DQS OSC ENi, and the semiconductor device 2000 independently of external control or input starts and stops the skew information generation operation for the logic unit LU0, for example, without receiving specific instructions, commands, or timing cues from the controller 3000 regarding when to start and stop the skew information generation operation.

The controller 3000 provides the write training internal processing enable command DQS OSC ENi to the semiconductor device 2000 and provides the skew information acquisition command DQS OSC GET FEATURE to the semiconductor device 2000 after a predetermined time period.

When the controller 3000 provides the skew information acquisition command DQS OSC GET FEATURE to the semiconductor device 2000, the semiconductor device 2000 provides the skew information to the controller 3000 in response to receiving the skew information acquisition command DQS OSC GET FEATURE.

When the controller 3000 provides a select chip termination command SCT to the semiconductor device 2000, the semiconductor device 2000 terminates the multi-operation function including write training by disabling the logic unit LU0 in response to receiving the select chip termination command SCT.

FIG. 7 and FIG. 8 illustrate an example in which a write training operation and a data input operation are performed as a multi-operation function. A multi-operation function in which a data output operation according to a read command and write training are performed in parallel and a multi-operation function in which an erase operation and a write training operation are performed in parallel may be performed in a manner similar to FIG. 7 and FIG. 8.

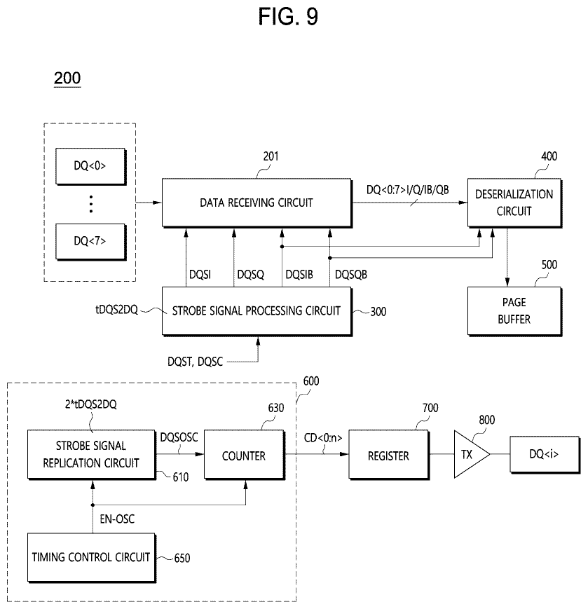

FIG. 9 is a diagram illustrating a configuration of a write training circuit 200 according to an embodiment of the present disclosure.

Referring to FIG. 9, the write training circuit 200 includes a data receiving circuit 201, a strobe signal processing circuit 300, and a skew detection circuit 600. The write training circuit 200 is included in the input/output circuit 160 of the semiconductor memory apparatus 100 shown in FIG. 5 but may alternatively be implemented elsewhere in the semiconductor memory apparatus 100.

The data receiving circuit 201 receives data and multi-phase clock signals DQSI, DQSQ, DQSIB, DQSQB as input and outputs received data DQ<0:7>I/Q/IB/QB. The data receiving circuit 201 generates the received data DQ<0:7>I/Q/IB/QB by receiving data input through the input/output pads DQ<0:7> according to the multi-phase clock signals DQSI, DQSQ, DQSIB, DQSQB.

The received data DQ<0:7>I/Q/IB/QB are transmitted to a deserialization circuit 400. The deserialization circuit 400 deserializes the received data DQ<0:7>I/Q/IB/QB according to clock signals DQSIB, DQSQB of the multi-phase clock signals DQSI, DQSQ, DQSIB, DQSQB and transmits the received data DQ<0:7>I/Q/IB/QB to a page buffer 500.

The strobe signal processing circuit 300 receives data strobe signals DQST, DQSC as input and outputs the multi-phase clock signals DQSI, DQSQ, DQSIB, DQSQB. The strobe signal processing circuit 300 divides the data strobe signals DQST, DQSC and delays the result by a predetermined time period to generate the multi-phase clock signals DQSI, DQSQ, DQSIB, DQSQB. The time from when the data strobe signals DQST, DQSC are input to the strobe signal processing circuit 300 to when the multi-phase clock signals DQSI, DQSQ, DQSIB, DQSQB are generated, or the multi-phase clock signals DQSI, DQSQ, DQSIB, DQSQB are output by the strobe signal processing circuit 300, is referred to as a first signal processing delay time tDQS2DQ.

The configuration of the skew detection circuit 600 is similar to the configuration of the strobe signal processing circuit 300 and generates a replication clock signal DQSOSC corresponding to any one of the multi-phase clock signals DQSI, DQSQ, DQSIB, DQSQB and generates skew information CD<0:n> according to the replication clock signal DQSOSC. The skew detection circuit 600 selectively performs an operation including generating the skew information CD<0:n> based on external control or internal control (independently of external control) depending on whether the write training internal processing enable command DQS OSC ENi is input or enabled. The skew information CD<0:n> is stored in a register 700 and transmitted through a transmitter TX 800 to the controller, for example, to a controller or device outside the semiconductor memory apparatus or outside the semiconductor device through one DQ<i> of the input/output pads DQ<0:7>.

The skew detection circuit 600 includes a strobe signal replication circuit 610, a counter 630, and a timing control circuit 650.

The configuration of the strobe signal replication circuit 610 is similar to the circuit configuration of the strobe signal processing circuit 300. The strobe signal replication circuit 610 generates a replication clock signal DQSOSC during a time period during which an oscillation enable signal EN-OSC is active. The time between the strobe signal replication circuit 610 initiating an oscillation operation and generating the replication clock signal DQSOSC is referred to as a second signal processing delay time 2*tDQS2DQ. The second signal processing delay time 2*tDQS2DQ is twice the size as the first signal processing delay time tDQS2DQ. Setting the second signal processing delay time 2*tDQS2DQ to twice the first signal processing delay time tDQS2DQ is provided as an example to facilitate the generation of skew information CD<0:n>, although the second signal processing delay time may be the same as the first signal processing delay time tDQS2DQ or may be set at an integer multiple of the first signal processing delay time tDQS2DQ.

The counter 630 generates the skew information CD<0:n> by counting edges of the replication clock signal DQSOSC during a time period during which the oscillation enable signal EN-OSC is active, for example, at a logic high level. For example, counting the edges of the replication clock signal DQSOSC includes counting rising edges of the replication clock signal DQSOSC, counting falling edges of the replication clock signal DQSOSC, or counting both rising edges and falling edges of the replication clock signal DQSOSC.

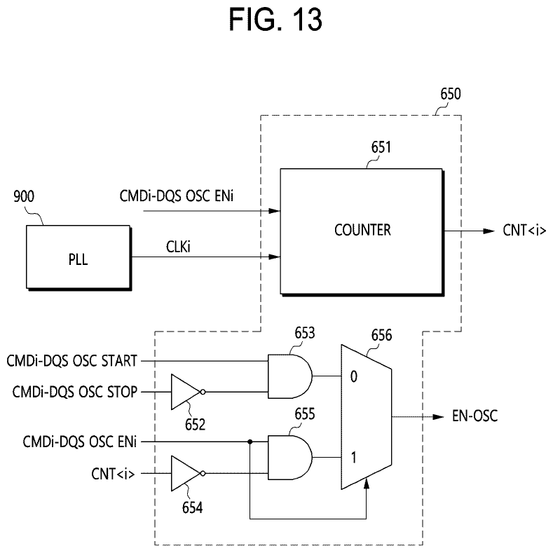

The timing control circuit 650 generates the oscillation enable signal EN-OSC in response to a plurality of timing control signals, for example, as described with respect to FIG. 13.

The controller 3000 transmits data to the semiconductor device according to rising edges and falling edges of each of the data strobe signals DQST, DQSC. Accordingly, at least one semiconductor memory apparatus or logic unit 100 of the semiconductor device 2000 divides and delays the data strobe signals DQST, DQSC using the strobe signal processing circuit 300 to generate multi-phase clock signals DQSI, DQSQ, DQSIB, DQSQB corresponding to the rising and falling edges of each of the data strobe signals DQST, DQSC. The data receiving circuit 201 receives the data according to the multi-phase clock signals DQSI, DQSQ, DQSIB, DQSQB to generate the received data DQ<0:7>I/Q/IB/QB.

The first signal processing delay time tDQS2DQ is a value set to optimize data sampling timing and changes along with voltage and/or temperature changes. When the first signal processing delay time tDQS2DQ changes, skew between the timing of the data and the multi-phase clock signals DQSI, DQSQ, DQSIB, DQSQB occurs, and normal data reception may not be possible. The skew information CD<0:n> resulting from detecting a change in the first signal processing delay time tDQS2DQ through the skew detection circuit 600 is transmitted to the controller 3000, and the controller 3000 accordingly performs a write training operation, during which the controller 3000 adjusts timing of the data strobe signals DQST, DQSC according to the skew information CD<0:n> provided by the semiconductor device 2000 to the controller 3000.

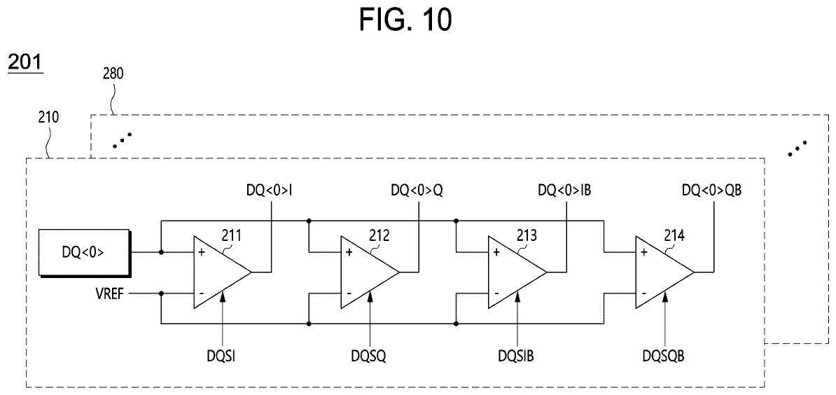

FIG. 10 is a diagram illustrating a configuration of the data receiving circuit 201, for example, as shown in FIG. 9.

Referring to FIG. 10, the data receiving circuit 201 includes a plurality of data receiving units 210, 220, 230, 240, 250, 260, 270, and 280. The plurality of data receiving units 210 through 280 have a one-to-one connection with a different one of the input/output pads DQ<0:7>.

The first data receiving unit 210 outputs a first received data subset DQ<0>I/Q/IB/QB of the received data DQ<0:7>I/Q/IB/QB by comparing the data input through the input/output pad DQ<0> with a reference voltage VREF at timing corresponding to each of the multi-phase clock signals DQSI, DQSQ, DQSIB, DQSQB.

The second data receiving unit 220 outputs a second received data subset DQ<1>I/Q/IB/QB of the received data DQ<0:7>I/Q/IB/QB by comparing the data input through the input/output pad DQ<1> with the reference voltage VREF at timing corresponding to each of the multi-phase clock signals DQSI, DQSQ, DQSIB, DQSQB.

The third data receiving unit 230 outputs a third received data subset DQ<2>I/Q/IB/QB of the received data DQ<0:7>I/Q/IB/QB by comparing the data input through the input/output pad DQ<2> with the reference voltage VREF at timing corresponding to each of the multi-phase clock signals DQSI, DQSQ, DQSIB, DQSQB.

The fourth data receiving unit 240 outputs a fourth received data subset DQ<3>I/Q/IB/QB of the received data DQ<0:7>I/Q/IB/QB by comparing the data input through the input/output pad DQ<3> with the reference voltage VREF at timing corresponding to each of the multi-phase clock signals DQSI, DQSQ, DQSIB, DQSQB.

The fifth data receiving unit 250 outputs a fifth received data subset DQ<4>I/Q/IB/QB of the received data DQ<0:7>I/Q/IB/QB by comparing the data input through the input/output pad DQ<4> with the reference voltage VREF at timing corresponding to each of the multi-phase clock signals DQSI, DQSQ, DQSIB, DQSQB.

The sixth data receiving unit 260 outputs a sixth received data subset DQ<5>I/Q/IB/QB of the received data DQ<0:7>I/Q/IB/QB by comparing the data input through the input/output pad DQ<5> with the reference voltage VREF at timing corresponding to each of the multi-phase clock signals DQSI, DQSQ, DQSIB, DQSQB.

The seventh data receiving unit 270 outputs a seventh received data subset DQ<6>I/Q/IB/QB of the received data DQ<0:7>I/Q/IB/QB by comparing the data input through the input/output pad DQ<6> with the reference voltage VREF at timing corresponding to each of the multi-phase clock signals DQSI, DQSQ, DQSIB, DQSQB.

The eighth data receiving unit 280 outputs an eighth received data subset DQ<7>I/Q/IB/QB of the received data DQ<0:7>I/Q/IB/QB by comparing the data input through the input/output pad DQ<7> with the reference voltage VREF at timing corresponding to each of the multi-phase clock signals DQSI, DQSQ, DQSIB, DQSQB.

Because the receiving units 210 through 280 are configured similarly to each other, only a configuration of the first data receiving unit 210 is illustrated, and the configuration of the first data receiving unit 210 is described for simplicity.

The first data receiving unit 210 includes a plurality of comparators 211 through 214. Each of the plurality of comparators 211 through 214 includes a first input terminal (+) in common with an input/output pad DQ<0> and a second input terminal (−) receiving a reference voltage VREF in common.

The first comparator 211 compares data input through the input/output pad DQ<0> to the reference voltage VREF during a time period while the first phase clock signal DQSI is at a logic high level and outputs a result as first received data DQ<0>I among the received data DQ<0:7>I/Q/IB/QB.

The second comparator 212 compares data input through the input/output pad DQ<0> to the reference voltage VREF during a time period while the second phase clock signal DQSQ is at a logic high level, and outputs a result as second received data DQ<0> Q among the received data DQ<0:7>I/Q/IB/QB.

The third comparator 213 compares data input through the input/output pad DQ<0> to the reference voltage VREF during a time period while the third phase clock signal DQSIB is at a logic high level, and outputs a result as third received data DQ<0>IB among the received data DQ<0:7>I/Q/IB/QB.

The fourth comparator 214 compares data input through the input/output pad DQ<0> to the reference voltage VREF during a time period while the fourth phase clock signal DQSQB is at a logic high level, and outputs a result as fourth received data DQ<0>QB among the received data DQ<0:7>I/Q/IB/QB.

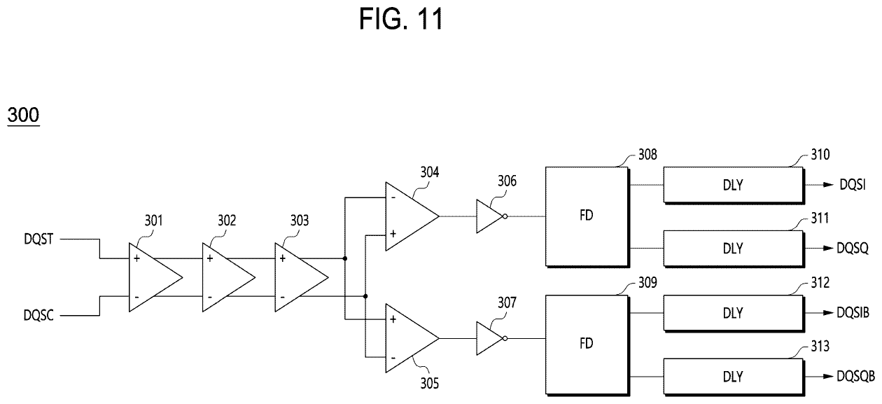

FIG. 11 is a diagram illustrating a configuration of the strobe signal processing circuit 300, for example, as shown in FIG. 9.

Referring to FIG. 11, the strobe signal processing circuit 300 includes amplification circuits, also known as amplifiers, 301 through 305, inverters 306, 307, divider circuits (FD) 308, 309, and delay circuits (DLY) 310 through 313.

The first amplification circuit 301, the second amplification circuit 302, and the third amplification circuits 303 amplify a difference between the data strobe signal DQST and the data strobe signal DQSC and outputs amplified signals. The fourth amplification circuit 304 receives differential output signals from the third amplification circuit 303 through input terminals of opposite phase and amplifies a difference between the received differential output signals. The fifth amplification circuit 305 receives differential output signals from the third amplification circuit 303 through input terminals of similar phase and amplifies a difference between the received differential output signals.

The first inverter 306 inverts an output of the fourth amplification circuit 304 and outputs the inverted output of the fourth amplification circuit 304. The second inverter 307 inverts an output of the fifth amplification circuit 305 and outputs the inverted output of the fifth amplification circuit 305.

The first divider circuit 308 divides and phase-separates an output of the first inverter 306 by a predetermined division ratio, for example, ½. The second divider circuit 309 divides and phase-separates an output of the second inverter 307 by a predetermined division ratio, for example, ½.

The first delay circuit 310 outputs a signal that delays a first output signal of the first divider circuit 308 by a first predetermined time period as the first phase clock signal DQSI. The second delay circuit 311 outputs a signal that delays a second output signal of the first divider circuit 308 by a second predetermined time period as the second phase clock signal DQSQ. The third delay circuit 312 outputs a signal that delays a first output signal of the second divider circuit 309 by a third predetermined time period as the third phase clock signal DQSIB. The fourth delay circuit 313 outputs a signal that delays a second output signal of the second divider circuit 309 by a fourth predetermined time period as the fourth phase clock signal DQSQB. The first predetermined time period, the second predetermined time period, the third predetermined time period, and the fourth predetermined time period may all be equal to the same time period or may be time periods having different values.

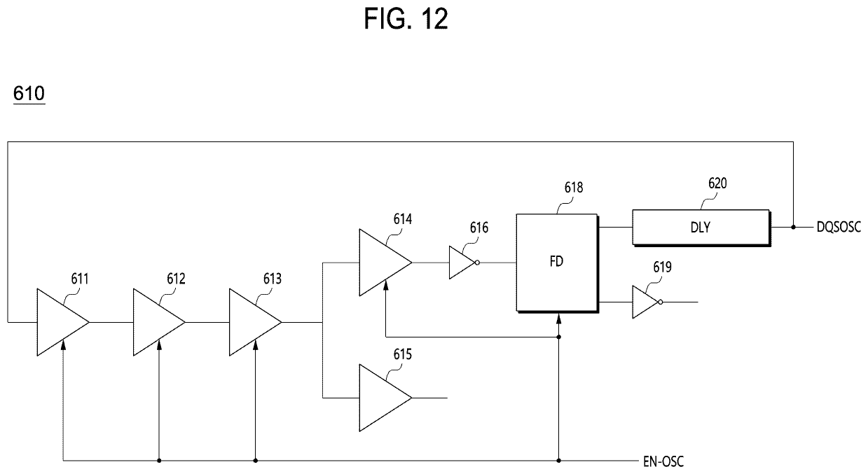

FIG. 12 is a diagram illustrating a configuration of the strobe signal replication circuit 610, for example, as shown in FIG. 9.

Referring to FIG. 12, the configuration of the strobe signal replication circuit 610 is a circuit having a similar configuration to the strobe signal processing circuit 300 of FIG. 9, as described above, and includes a circuit configuration that generates the replication clock signal DQSOSC corresponding to any of the multi-phase clock signals DQSI, DQSQ, DQSIB, and DQSQB, for example, the first phase clock signal DQSI. The strobe signal replication circuit 610 includes logic gates 611 through 616 and 618 through 620 corresponding to the amplifier circuits 301 through 305, the first inverter 306, the first divider circuit 308, and the first delay circuit 310 of FIG. 11. The logic gates 615, 619 are configured to match the loading of the strobe signal replication circuit 610 with the loading of the strobe signal processing circuit 300.

The strobe signal replication circuit 610 initiates generation of the replication clock signal DQSOSC in response to activation, for example, enabling at a logic high level, of an oscillation enable signal EN-OSC and performs an oscillation operation that generates the replication clock signal DQSOSC. The replication clock signal DQSOSC is fed back as the input to logic gate 611. The time between input of the replication clock signal DQSOSC to the logic gate 611 and output of the resulting processed signal by the delay 620 is 2*tDQS2DQ, as described with respect to FIG. 9.

FIG. 13 is a diagram illustrating a configuration of the timing control circuit 650, for example, as shown in FIG. 9.

Referring to FIG. 13, the timing control circuit 650 generates the oscillation enable signal EN-OSC in response to a plurality of timing control signals CMDi-DQS OSC Eni, CMDi-DQS OSC START, and CMDi-DQS OSC STOP. The timing control circuit 650 includes a counter 651, a plurality of logic gates 652 through 655, and a multiplexing circuit 656.

The counter 651 generates a counting signal CNT<i> by counting edges of an internal clock signal CLKi during a time period while the first timing control signal CMDi-DQS OSC Eni is active at a logic high level. For example, counting the edges of the internal clock signal CLKi includes counting rising edges of the internal clock signal CLKi, counting falling edges of the internal clock signal CLKi, or counting both rising edges and falling edges of the internal clock signal CLKi. The counter 651 generates a plurality of counting signals CNT<0: i>, where the quantity of edges counted for the internal clock signal CLKi are represented by bits 0 through i, where i is a positive integer, and outputs the counting signal CNT<i> for one bit i, each bit of the quantity of edges corresponding to one of the plurality of counting signals, for example, a most significant bit. The counter 651 initializes each of the plurality of counting signals to a logic low level at the time when the first timing control signal CMDi-DQS OSC Eni is activated, for example, when the first timing control signal CMDi-DQS OSC Eni transitions to a logic high level. The counter 651 is enabled by the first timing control signal CMDi-DQS OSC Eni.

The internal clock signal CLKi is provided by a phase-locked loop circuit PLL 900.

The first logic gate 652 and the second logic gate 653 output a result of a logical AND operation of a second timing control signal CMDi-DQS OSC START and an inverted third timing control signal CMDi-DQS OSC STOP of the plurality of timing control signals.

The third logic gate 654 and the fourth logic gate 655 output a result of a logical AND operation of the first timing control signal CMDi-DQS OSC ENi and an inverted counting signal CNT<i>.

The multiplexing circuit 656 selects and outputs one of an output of the second logic gate 653 and an output of the fourth logic gate 655 according to a logic level of the first timing control signal CMDi-DQS OSC ENi as the oscillation enable signal EN-OSC. The multiplexing circuit 656 outputs the output of the second logic gate 653 as the oscillation enable signal EN-OSC when the first timing control signal CMDi-DQS OSC ENi is at a logic low level and outputs the output of the fourth logic gate 655 as the oscillation enable signal EN-OSC when the first timing control signal CMDi-DQS OSC ENi is at a logic high level.

The first timing control signal CMDi-DQS OSC ENi, the second timing control signal CMDi-DQS OSC START, and the third timing control signal CMDi-DQS OSC STOP are generated by decoding commands such as external commands received from an external source such as the controller 3000. The first timing control signal CMDi-DQS OSC ENi is generated by decoding a write training internal processing enable command DQS OSC ENi, the second timing control signal CMDi-DQS OSC START is generated by decoding a write training start command DQS OSC START, and the third timing control signal CMDi-DQS OSC STOP is generated by decoding a write training stop command DQS OSC STOP.

When the multi-operation function including a write training is performed under the control of the controller 3000 (see FIG. 7), the first timing control signal CMDi-DQS OSC ENi is maintained at a logic low level because the write training internal processing enable command DQS OSC ENi is not presently input.

Because the first timing control signal CMDi-DQS OSC ENi is at a logic low level, the counter 651 is disabled or does not operate, and the multiplexing circuit 656 outputs the output of the second logic gate 653 as the oscillation enable signal EN-OSC. When the first timing control signal CMDi-DQS OSC ENi is at a logic low level, the timing control circuit 650 controls the strobe signal replication circuit 610 to generate skew information CD<0:n> in response to commands received from and provided by the controller 3000, for example, the write training start command DQS OSC START and the write training stop command DQS OSC STOP.

When the semiconductor device 2000 performs a subset of the operations of the multi-operation function including the write training independently of external control by the controller 3000 (see FIG. 8), the first timing control signal CMDi-DQS OSC ENi is at a logic high level while the write training internal processing enable command DQS OSC ENi is input or enabled.

Because the first timing control signal CMDi-DQS OSC ENi is at a logic high level, the counter 651 is enabled, and the multiplexing circuit 656 outputs the output of the fourth logic gate 655 as the oscillation enable signal EN-OSC. The timing control circuit 650 independently processes the operation including generating the skew information CD<0:n> by controlling the strobe signal replication circuit 610. When the semiconductor memory apparatus 100 or the semiconductor device 2000 performs a subset of the operations of the multi-operation function independently of external control, such as by the controller 3000, the external-control load associated with controlling the semiconductor memory apparatus 100 or the semiconductor device 2000 may be reduced, and the operation timing margins of the controller 3000 may be increased.

A person skilled in the art to which the present disclosure pertains understands that various modifications, additions, and substitutions related to the present disclosure may be carried out without departing from the scope and technical concepts of the present disclosure. The embodiments described above are illustrative, not limited. Therefore, the scope of the present disclosure is not limited to the above descriptions. All changes within the meaning and range of equivalency of the claims are included within their scope.

What is claimed is:

1. A write training circuit comprising:
a data receiving circuit configured to receive data input according to a plurality of multi-phase clock signals to generate received data;
a strobe signal processing circuit configured to generate the plurality of multi-phase clock signals by dividing a data strobe signal into divided signals and delaying the divided signals by a predetermined time period; and
a skew detection circuit configured to generate a replication clock signal corresponding to one of the plurality of multi-phase clock signals and configured to generate skew information according to the replication clock signal;
wherein the skew detection circuit is configured to generate the skew information under external control or independently of external control depending on which of a plurality of external commands is received.

2. The write training circuit of claim 1, wherein the skew detection circuit is configured to output the skew information to an external device in response to external control.

3. The write training circuit of claim 1, wherein the skew detection circuit comprises:
a strobe signal replication circuit configured similar to the strobe signal processing circuit and configured to generate the replication clock signal during a time period during which an oscillation enable signal is active;
a counter configured to generate the skew information by counting edges of the replication clock signal during the time period during which the oscillation enable signal is active; and
a timing control circuit configured to generate the oscillation enable signal in response to a plurality of timing control signals.

4. The write training circuit of claim 3, wherein the plurality of timing control signals are generated by decoding the plurality of external commands.

5. The write training circuit of claim 1, further comprising a deserialization circuit that deserializes the received data according to at least one of the plurality of multi-phase clock signals.

6. A semiconductor device comprising:
a semiconductor memory apparatus configured to perform a normal operation when a command for the normal operation is received and configured to perform a write training operation during a time period during which the normal operation is performed;
wherein the write training operation comprises internally multi-phase processing a data strobe signal provided from an external device to determine a time to latch data provided from the external device.

7. The semiconductor device of claim 6, wherein the normal operation includes at least one of a data input operation, a data output operation, and an erase operation.

8. The semiconductor device of claim 6, wherein the write training operation is performed under external control or independently of external control depending on which of a plurality of external commands is received.

9. The semiconductor device of claim 6, wherein the semiconductor device is further configured to:
perform a preparation operation for the write training operation for a corresponding logic unit when a write training enable command is received from the external device;
initiate an operation that generates skew information when a write training start command is received from the external device;
stop the operation that generates the skew information when a write training stop command is received from the external device; and
provide the skew information to the external device when a skew information acquisition command is received from the external device.

10. The semiconductor device of claim 6, wherein the semiconductor memory apparatus is configured to perform a preparation operation for the write training operation for a corresponding logic unit when a write training enable command is received from the external device and configured to perform starting and stopping of a skew information generation operation independently of external control for a predetermined time period.

11. The semiconductor device of claim 6, further comprising:
a data receiving circuit configured to receive the data input according to a plurality of multi-phase clock signals to generate received data;
a strobe signal processing circuit configured to generate the plurality of multi-phase clock signals by dividing the data strobe signal into divided signals and delaying the divided signals by a predetermined time period; and
a skew detection circuit configured to generate a replication clock signal corresponding to one of the plurality of multi-phase clock signals according to one of a plurality of external commands and configured to generate skew information according to the replication clock signal.

12. The semiconductor memory apparatus of claim 11, wherein the skew detection circuit comprises:
a strobe signal replication circuit configured similar to the strobe signal processing circuit and configured to generate the replication clock signal during a time period during which an oscillation enable signal is active;
a counter configured to generate the skew information by counting edges of the replication clock signal during the time period during which the oscillation enable signal is active; and
a timing control circuit configured to generate the oscillation enable signal in response to a plurality of timing control signals.

13. The semiconductor memory apparatus of claim 12, wherein the plurality of timing control signals are generated by decoding the plurality of external commands.

14. The semiconductor memory apparatus of claim 11, further comprising a deserialization circuit that deserializes the received data according to at least one of the plurality of multi-phase clock signals.

15. A data processing system comprising:
a semiconductor memory apparatus configured to perform a write training operation including determining a time to latch data according to a plurality of multi-phase clock signals that are internally generated based on a data strobe signal during a time period during which a normal operation is performed and outputting the time as skew information, configured to perform the write training operation under external control when a write training enable command is received, and configured to perform the write training operation independently of external control when a write training internal processing enable command is received; and
a controller configured to provide a plurality of commands including the write training enable command and the write training internal processing enable command, the data, and the data strobe signal to the semiconductor memory apparatus and configured to adjust timing of the data strobe signal according to the skew information.

16. The data processing system of claim 15, wherein the normal operation includes at least one of a data input operation, a data output operation, and an erase operation.

17. The data processing system of claim 15, wherein the semiconductor memory apparatus is further configured to:
perform a preparation operation for the write training operation for a corresponding logic unit when the write training enable command is received;
initiate an operation that generates the skew information when a write training start command is received from the controller;
stop the operation that generates the skew information when a write training stop command is received from the controller; and
provide the skew information to the controller when a skew information acquisition command is received from the controller.

18. The data processing system of claim 15, wherein the semiconductor memory apparatus is configured to perform a preparation operation for the write training operation for a corresponding logic unit when the write training enable command is received from the controller and configured to perform, independently of control by the controller, starting and stopping generating the skew information for a predetermined time period.

19. The data processing system of claim 15, wherein the semiconductor memory apparatus comprises:
a data receiving circuit configured to receive the data input according to the plurality of multi-phase clock signals to generate received data;
a strobe signal processing circuit configured to generate the plurality of multi-phase clock signals by dividing the data strobe signal into divided signals and delaying the divided signals by a predetermined time period; and
a skew detection circuit configured to generate a replication clock signal corresponding to one of the plurality of multi-phase clock signals according to the write training internal processing enable command and configured to generate the skew information according to the replication clock signal.

20. The data processing system of claim 19, wherein the skew detection circuit comprises:
a strobe signal replication circuit configured similar to the strobe signal processing circuit and configured to generate the replication clock signal during a time period during which an oscillation enable signal is active;
a counter configured to generate the skew information by counting edges of the replication clock signal during the time period during which the oscillation enable signal is active; and
a timing control circuit configured to generate the oscillation enable signal in response to a plurality of timing control signals generated by decoding the plurality of commands.
